(19) United States
(12) Patent Application Publication
(10) Pub. No.: US 2025/0159980 A1
(43) Pub. Date: May 15, 2025

(54) STACKED TRANSISTOR DEVICE FORMED USING MULTI-LAYER DUMMY GATE

(71) Applicant: Samsung Electronics Co., Ltd., Suwon-si (KR)

(72) Inventors: Seungchan Yun, Waterford, NY (US); Panjae Park, Halfmoon, NY (US); Kang-ill Seo, Springfield, VA (US)

(21) Appl. No.: 18/758,376

(22) Filed: Jun. 28, 2024

Related U.S. Application Data
(60) Provisional application No. 63/548,052, filed on Nov. 10, 2023.

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/017; H10D 84/0167; H10D 84/0188; H10D 84/038; H10D 88/01

(57) ABSTRACT

Stacked field-effect transistor (FET) devices are provided. A stacked FET device includes a lower FET having lower channel layers and a lower gate material that is between the lower channel layers. The stacked FET device includes an upper FET that is on the lower FET. The upper FET has upper channel layers and an upper gate material that is between the upper channel layers. Moreover, the stacked FET device includes an insulating layer that is between the lower gate material and the upper gate material and not in a region in which the lower channel layers are overlapped by the upper channel layers. Related methods of forming stacked FET devices are also provided.

### RELATED APPLICATIONS

The present application claims the benefit of U.S. Provisional Patent Application Ser. No. 63/548,052, filed on Nov. 10, 2023, entitled METHOD OF CO-INTEGRATION OF STACKED FIELD-EFFECT TRANSISTOR WITH SEPARATE GATE STRUCTURE AND STACKED FIELD-EFFECT TRANSISTOR WITH COMMON GATE STRUCTURE USING TRI-LAYER DUMMY GATE STRUCTURE, the disclosure of which is hereby incorporated herein in its entirety by reference.

### TECHNICAL FIELD

The present disclosure generally relates to the field of semiconductor devices and, more particularly, to three-dimensional transistor structures.

### BACKGROUND OF THE INVENTION

The size of transistors in integrated circuit (IC) devices has continued to decrease to down-scale logic elements. This has resulted in the development of gate-all-around (GAA) structures such as multi-bridge channel field-effect transistors (MBCFETs™) and nanosheet FETs (NSFETs). Moreover, as technology to increase transistor density has continued to develop, three-dimensional device structures, such as stacked transistors, are under consideration.

A stacked transistor (or a “transistor stack”) may include a first transistor and a second transistor. The first transistor may be a first type of transistor (e.g., an n-type metal-oxide-semiconductor (NMOS) transistor) and the second transistor may be a second type of transistor (e.g., a p-type metal-oxide-semiconductor (PMOS) transistor). The first and second types of transistors may be complementary to each other, and thus may be part of a complementary metal-oxide-semiconductor (CMOS) IC. The first and second transistors may be stacked in any order (e.g., first on top of second, or second on top of first), thereby resulting in a stack comprising a top/upper transistor and a bottom/lower transistor.

### SUMMARY OF THE INVENTION

A stacked FET device, according to some embodiments herein, may include a lower FET having lower channel layers and a lower gate material that is between the lower channel layers. The stacked FET device may include an upper FET that is on the lower FET. The upper FET may have upper channel layers and an upper gate material that is between the upper channel layers. Moreover, the stacked FET device may include an insulating layer that is between the lower gate material and the upper gate material and not in a region in which the lower channel layers are overlapped by the upper channel layers.

A stacked FET device, according to some embodiments herein, may include a lower FET having lower channel layers and a lower gate material that is between the lower channel layers. The stacked FET device may include an upper FET that is on the lower FET. The upper FET may include upper channel layers and an upper gate material that is between the upper channel layers. The stacked FET device may include an isolation region that separates the lower channel layers from the upper channel layers. Moreover, the stacked FET device may include an insulating layer that separates the lower gate material from the upper gate material and is adjacent a sidewall of the isolation region.

A method of forming a stacked FET device, according to some embodiments herein, may include forming a nanosheet stack and a multi-layer dummy gate structure on the nanosheet stack. The nanosheet stack may include lower channel layers and upper channel layers that are on the lower channel layers. The multi-layer dummy gate structure may include an upper semiconductor sacrificial layer, a lower semiconductor sacrificial layer, and an etch-stop layer that is between the lower semiconductor sacrificial layer and the upper semiconductor sacrificial layer. The method may include removing the upper semiconductor sacrificial layer to expose an upper surface of the etch-stop layer. The method may include forming an upper gate material between the upper channel layers and on the upper surface of the etch-stop layer. The method may include removing the lower semiconductor sacrificial layer to expose a lower surface of the etch-stop layer, after forming the upper gate material. Moreover, the method may include forming a lower gate material between the lower channel layers, after removing the lower semiconductor sacrificial layer.

### BRIEF DESCRIPTION OF THE DRAWINGS

FIG. 1A is a schematic block diagram of a transistor stack of a transistor device according to some embodiments herein.

FIG. 1B is an example plan view of the transistor device of FIG. 1A.

FIG. 1C is an example cross-sectional view of the transistor device of FIG. 1B along the line A-A′.

FIG. 1D is an example cross-sectional view of the transistor device of FIG. 1B along the line B-B′.

FIG. 1E is an example cross-sectional view of the transistor device of FIG. 1B along the line C-C′.

FIG. 1F is an example cross-sectional view of the transistor device of FIG. 1B along the line D-D′.

FIG. 2A is another example cross-sectional view of the transistor device of FIG. 1B along the line A-A′.

FIG. 2B is another example cross-sectional view of the transistor device of FIG. 1B along the line B-B′.

FIG. 2C is another example cross-sectional view of the transistor device of FIG. 1B along the line C-C′.

FIGS. 3A-3AG are cross-sectional views illustrating operations of forming the transistor device of FIGS. 1C-1F.

FIGS. 4A-4C are cross-sectional views illustrating an operation/process of forming the transistor device of FIGS. 2A-2C.

FIG. 5 is a flowchart corresponding to the operations shown in FIGS. 3A-3AG and 4A-4C.

### DETAILED DESCRIPTION

Pursuant to embodiments herein, stacked transistor devices are provided that are formed using multi-layer dummy gate structures. A multi-layer dummy gate structure can provide improved (e.g., easier) control of a process variation for different upper and lower gate materials (e.g., an upper work-function metal (WFM) and a lower WFM) of upper and lower transistors, respectively, in a transistor stack. According to some embodiments, an intermediate (e.g., middle) layer of the multi-layer dummy gate structure may serve as an etch-stop layer and may separate the upper gate material from the lower gate material. For example, the etch-stop layer may be an insulating layer that remains between the upper gate material and the lower gate material in a final transistor stack structure, thereby providing a separated gate structure in which the upper gate material and the lower gate material are separated (and electrically isolated) from each other. The separated gate structure may be more helpful than a common gate structure for reducing an area used by a transistor stack, such as in a cross-couple structure for a static random-access memory (SRAM) device.

In other embodiments, the etch-stop layer may be removed before forming the lower gate material, thereby facilitating the formation of a common gate structure, in which the upper gate material and the lower gate material are in contact with each other. Moreover, multi-layer dummy gate structures may, in some embodiments, be used to selectively form both a separated gate structure and a common gate structure (e.g., in different regions, respectively, of a transistor device) in the same integration/process flow.

Example embodiments will be described in greater detail with reference to the attached figures.

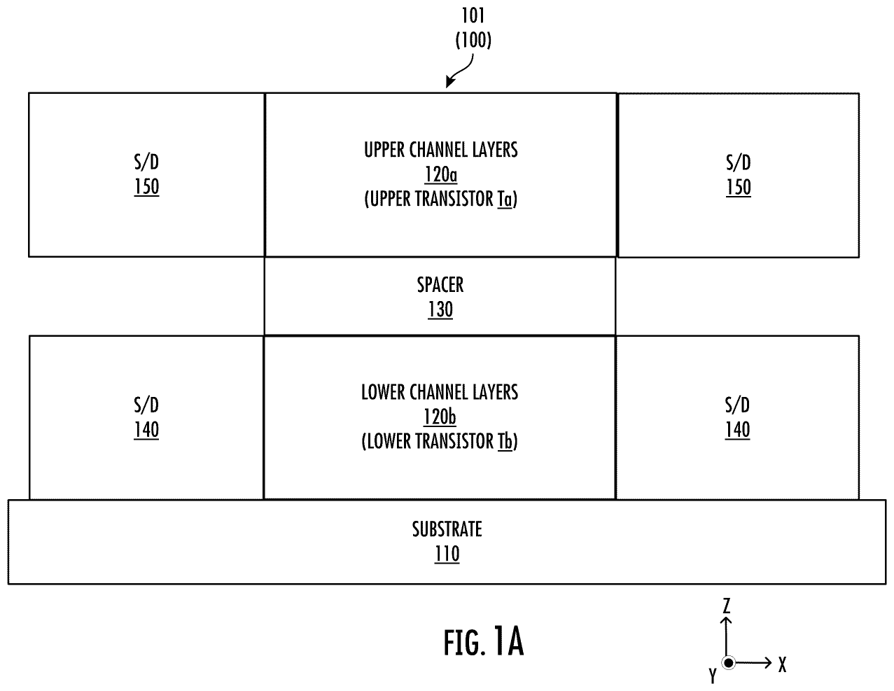

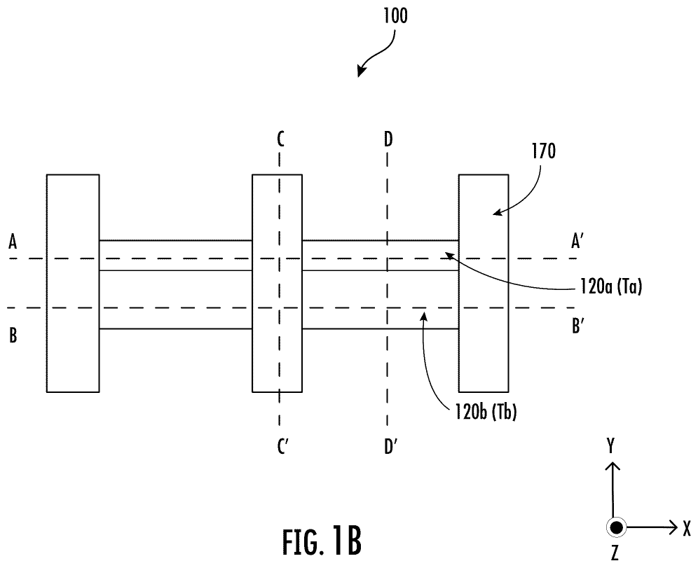

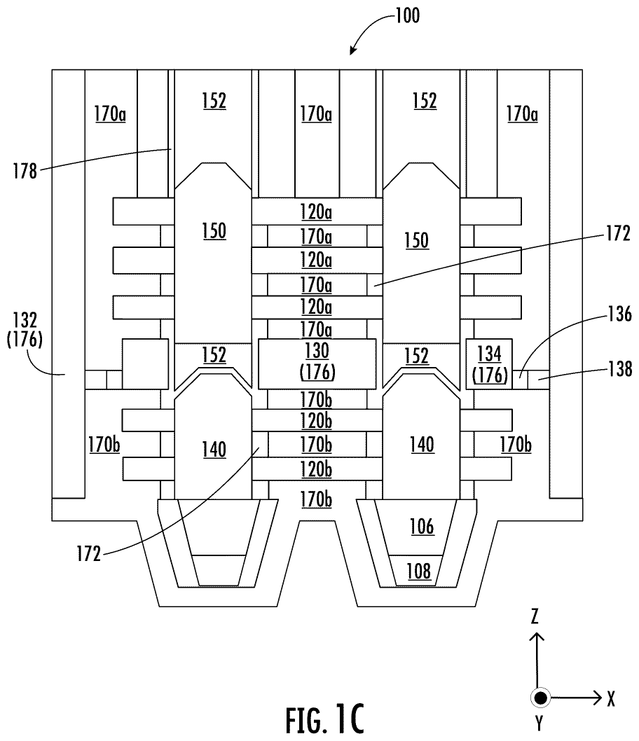

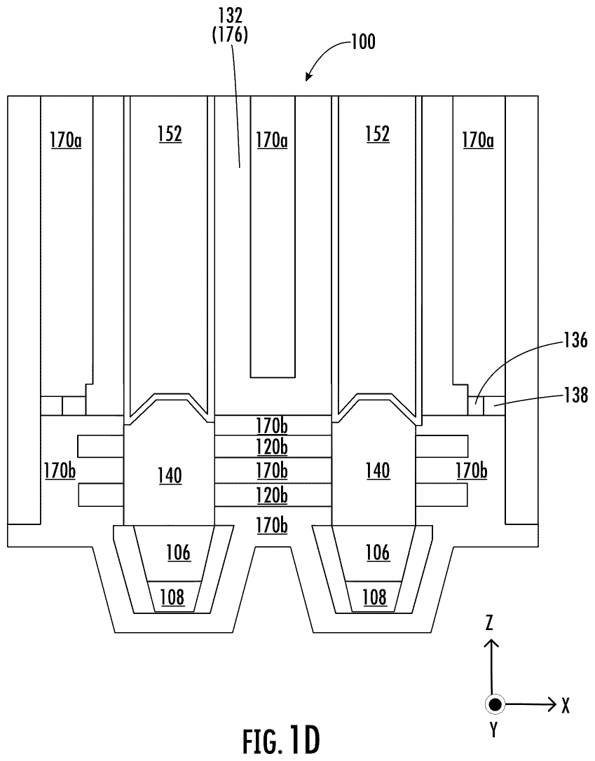

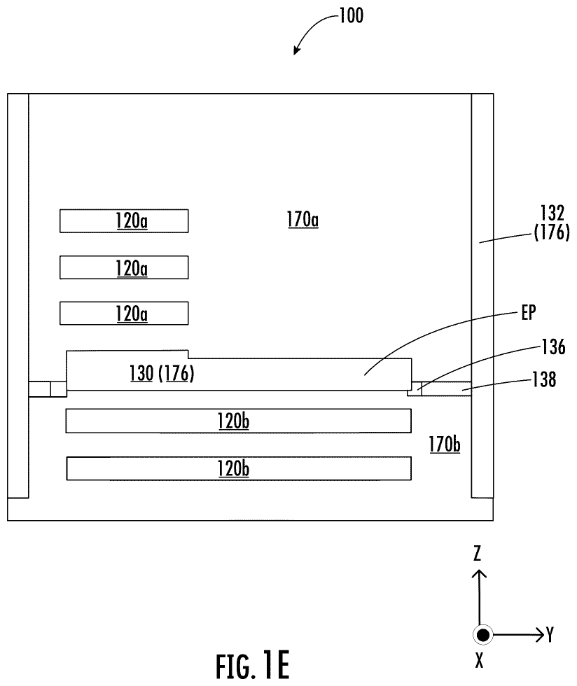

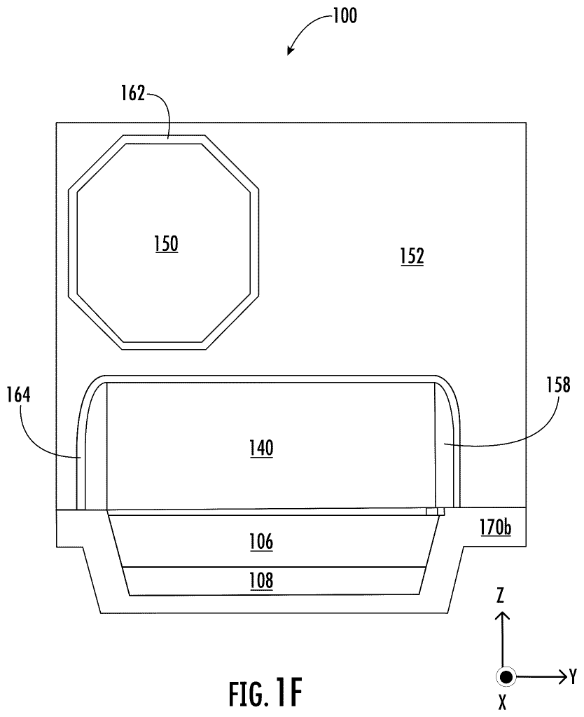

FIG. 1A is a schematic block diagram of a transistor stack 101 of a transistor device 100 according to some embodiments herein. The transistor stack 101 includes a lower transistor Tb having a stack of lower semiconductor channel layers 120b and an upper transistor Ta having a stack of upper semiconductor channel layers 120a. The channel layers 120a, 120b may comprise, for example, silicon and may be free of (i.e., do not include) germanium and carbon. The lower transistor Tb is between, in a vertical direction Z, the upper transistor Ta and a substrate 110 (e.g., a silicon, or other semiconductor, substrate). Moreover, an isolation layer/region 130, such as a middle dielectric isolation (MDI) layer/region, may, in some embodiments, serve as a spacer between the lower and upper transistors Ta, Tb. The isolation layer/region 130 may thus be referred to herein as a “spacer.”

The lower channel layers 120b of the lower transistor Tb are between, in a first horizontal (i.e., lateral) direction X, a pair of lower source/drain (S/D) regions 140 that are electrically connected to the lower channel layers 120b. The first horizontal direction X and the vertical direction Z may be perpendicular to each other, and a second horizontal (i.e., lateral) direction Y may be perpendicular to each of the first horizontal direction X and the vertical direction Z. Each lower channel layer 120b may be implemented by, for example, a nanosheet or nanowire between the lower S/D regions 140. Likewise, the upper channel layers 120a of the upper transistor Ta may be between, in the first horizontal direction X, a pair of upper S/D regions 150 that are electrically connected to the upper channel layers 120a, and each upper channel layer 120a may be implemented by, for example, a nanosheet or nanowire between the upper S/D regions 150.

In some embodiments, the upper S/D regions 150 may include a different semiconductor material from that of the lower S/D regions 140. As an example, the upper S/D regions 150 may include silicon germanium, and the lower S/D regions 140 may include silicon carbide, or vice versa. In other embodiments, the upper S/D regions 150 may include the same semiconductor material as the lower S/D regions 140.

For simplicity of illustration, only one transistor stack 101 is shown in FIG. 1A. According to some embodiments, however, the device 100 may include two, three, four, or more transistor stacks 101.

FIG. 1B is an example plan view of the transistor device 100. As shown in FIG. 1B, the device 100 includes one or more gates 170 on the upper channel layers 120a of the upper transistor Ta and the lower channel layers 120b of the lower transistor Tb. The gates 170 may each comprise one or more conductive materials, such as one or more WFMs.

A line A-A′ extends along a channel width of the upper channel layers 120a of the upper transistor Ta in the lateral direction X. A line B-B′ extends along a channel width of the lower channel layers 120b of the lower transistor Tb in the lateral direction X. The lines A-A′ and B-B′ are spaced apart from each other in the other lateral direction Y. A line C-C′ passes lengthwise (i.e., longitudinally) through a gate 170 in the other lateral direction Y. A line D-D′ passes through the upper transistor Ta and the lower transistor Tb, without passing through a gate 170, in the other lateral direction Y. The lines C-C′ and D-D′ are spaced apart from each other in the lateral direction X.

FIG. 1C is an example cross-sectional view of the transistor device 100 along the line A-A′ of FIG. 1B. As shown in FIG. 1C, an upper gate 170a may be on the upper channel layers 120a of the upper transistor Ta of the transistor stack 101 (FIG. 1A), and a lower gate 170b may be on the lower channel layers 120b of the lower transistor Tb (FIG. 1A) of the transistor stack 101. The upper gate 170a is an upper conductive gate (e.g., an upper WFM layer) that may be between (in the vertical direction Z) the upper channel layers 120a, and may be spaced apart from the upper S/D regions 150 in the direction X by insulating spacers 172. The spacers 172 may be on sidewalls of the upper gate 170a and between, in the vertical direction Z, the upper channel layers 120a.

Likewise, the lower gate 170b is a lower conductive gate (e.g., a lower WFM layer) that may be between (in the vertical direction Z) the lower channel layers 120b. The lower gate 170b may be spaced apart from the lower S/D regions 140 in the direction X by spacers 172, which may be on sidewalls of the lower gate 170b and between, in the vertical direction Z, the lower channel layers 120b. In some embodiments, the spacers 172 may contact the lower S/D regions 140, the upper S/D regions 150, sidewalls of the lower gate 170b, and sidewalls of the upper gate 170a. Sidewalls of the lower channel layers 120b may contact the lower S/D regions 140, and sidewalls of the upper channel layers 120a may contact the upper S/D regions 150.

The upper gate 170a and the lower gate 170b may each include a metal or a semiconductor material. The metal or semiconductor material of the upper gate 170a may be referred to herein as an “upper gate material,” and the metal or semiconductor material of the lower gate 170b may be referred to herein as a “lower gate material,” where the upper and lower gate materials may be different materials. As an example, the upper gate 170a and the lower gate 170b may comprise different metals, respectively. In some embodiments, the metals may be different WFMs, respectively. For example, the lower gate 170b may comprise a lower WFM layer that comprises aluminum, as the lower transistor Tb (FIG. 1A) may be an NMOS transistor, and the upper gate 170a may comprise an upper WFM layer of titanium nitride, as the upper transistor Ta (FIG. 1A) may be a PMOS transistor. Moreover, tungsten (or another metal) may be formed on the lower WFM layer and/or the upper WFM layer. Accordingly, the lower gate 170b may comprise the lower WFM layer and tungsten (or another metal), and the upper gate 170a may comprise the upper WFM layer and tungsten (or another metal).

According to some embodiments, the spacers 172 may comprise, for example, nitrogen (e.g., silicon nitride). The spacers 172 may also be referred to herein as “inner spacers,” as they may be situated between nanosheet/nanowire channels within a transistor.

The upper and lower transistors Ta, Tb may be different types of MOSFETs. The transistor device 100 may thus be a stacked FET device. For example, the upper and lower transistors Ta, Tb may be PMOS and NMOS transistors, respectively, or vice versa. As an example, PMOS and NMOS transistors may be provided by S/D regions comprising silicon germanium and silicon carbide, respectively. In some embodiments, the spacer 130 may separate the lower channel layers 120b of the lower transistor Tb from the upper channel layers 120a of the upper transistor Ta. The spacer 130 may comprise, for example, silicon boron carbonitride (SiBCN).

For simplicity of illustration, a gate insulation layer is omitted from view in FIG. 1C. It will be understood, however, that a gate insulation layer may extend between each channel layer 120 and a gate 170. The gate insulation layer may wrap around each channel layer 120 and may be thinner than the spacer 130.

According to some embodiments, an insulating layer 152 may be between, in the vertical direction Z, the lower and upper S/D regions 140, 150. Moreover, the insulating layer 152 may be on an upper surface of each of the upper S/D regions 150. An insulating layer 132 may be on sidewalls of the gates 170a, 170b, and an insulating layer 134 may be between the upper gate 170a and the lower gate 170b. An insulating layer 178 may be between the insulating layer 132 and the insulating layer 152, and between the insulating layer 134 and the insulating layer 152.

The insulating layers 132, 134 may comprise the same insulating material (e.g., SiBCN) as the spacer 130, and this insulating material may be different from an insulating material of the insulating layer 152. For example, the insulating layers 132, 134 and the spacer 130 may each be part of an insulating structure/layer 176 (i.e., the same insulating material). As an example, vertical portions of insulating material 176 may be provided by the insulating layer 132, and lateral portions of the insulating material 176 may be provided by the spacer 130 and the insulating layer 134. The spacer 130 may thus be referred to herein as a “lateral portion” of the insulating material 176, and the insulating layer 132 may be referred to herein as a “vertical portion” (or “vertical portions”) of the insulating material 176.

An insulating layer 136 may be on a sidewall of the insulating layer 134. In some embodiments, the insulating layer 136 may comprise the same insulating material as that of the insulating layer 152. The insulating material may be different from that of the spacer 130. As an example, the insulating layers 136, 152 may each comprise an oxide (e.g., silicon oxide). According to some embodiments, the oxide may be free of carbon and free of boron.

The device 100 may include an insulating layer 138 that is between, in the vertical direction Z, the upper gate 170a and the lower gate 170b. For example, the insulating layer 138 may contact a lower surface of the upper gate 170a and an upper surface of the lower gate 170b. The insulating layers 136, 138 may be relatively thin layers. As an example, the insulating layers 136, 138 may each be thinner, in the vertical direction Z, than the spacer 130 (and thinner than the insulating layer 134). In some embodiments, the insulating layers 136, 138 may each be less than half the thickness of the spacer 130 (and less than half the thickness of the insulating layer 134).

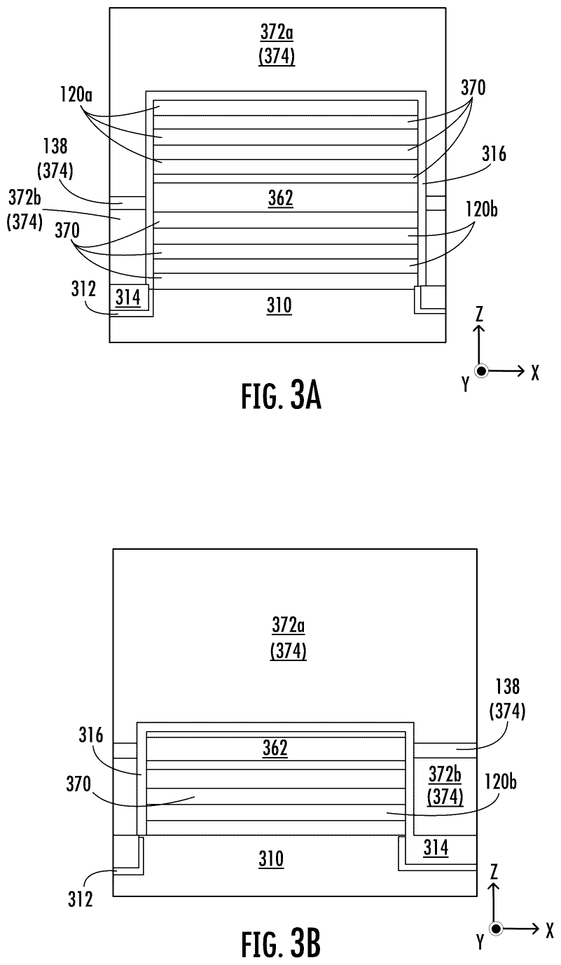

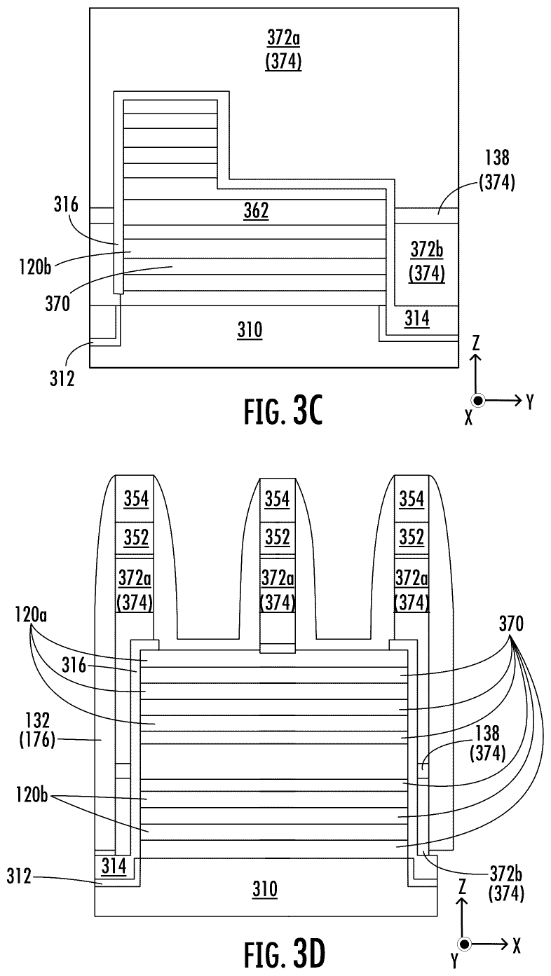

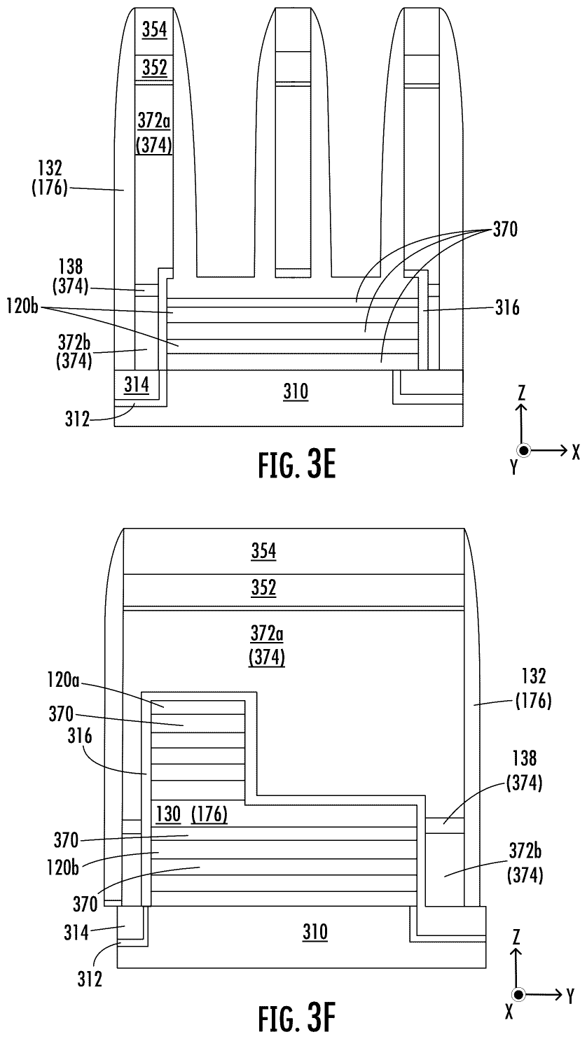

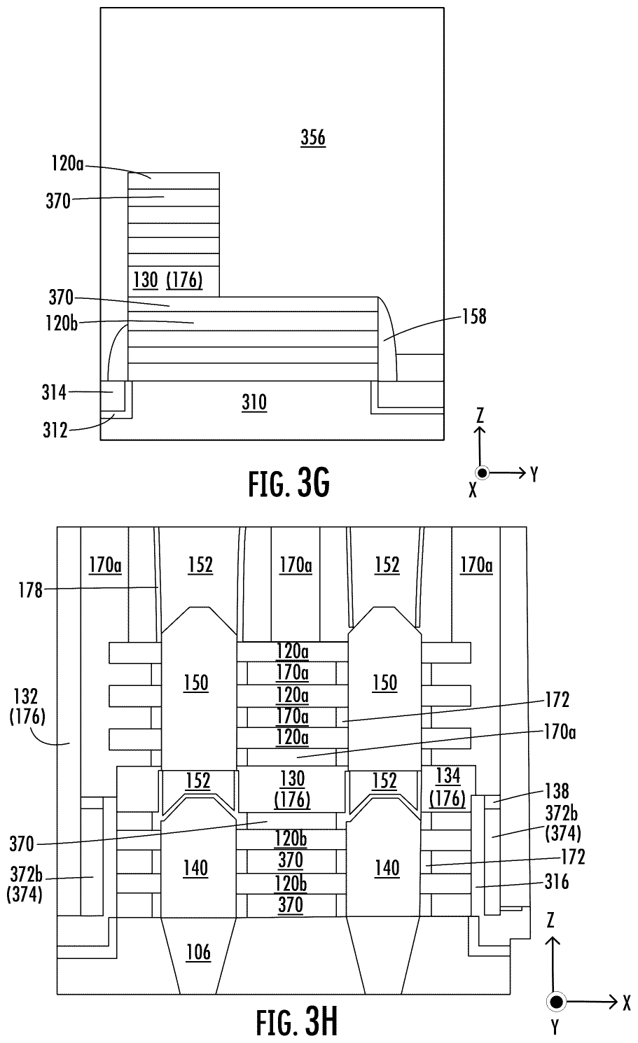

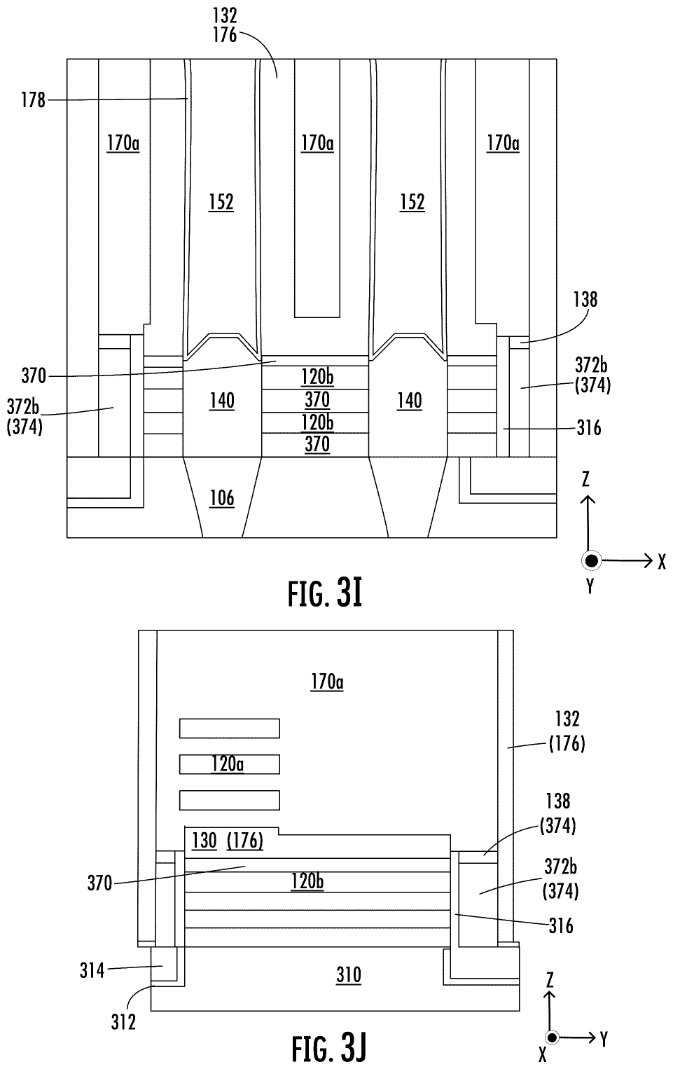

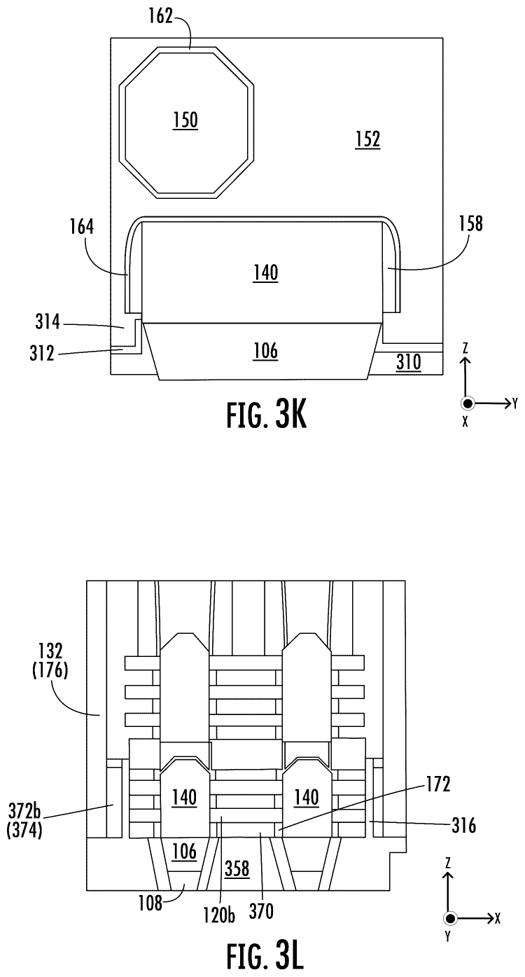

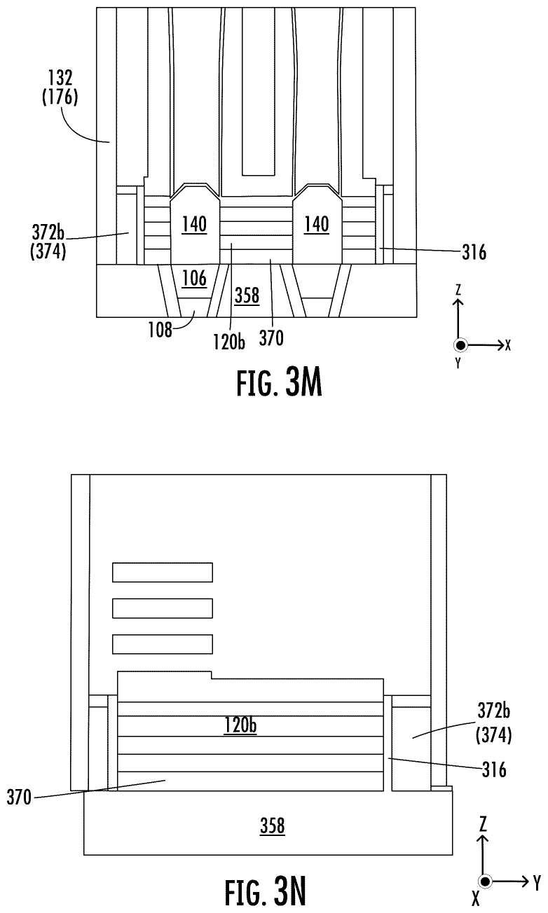

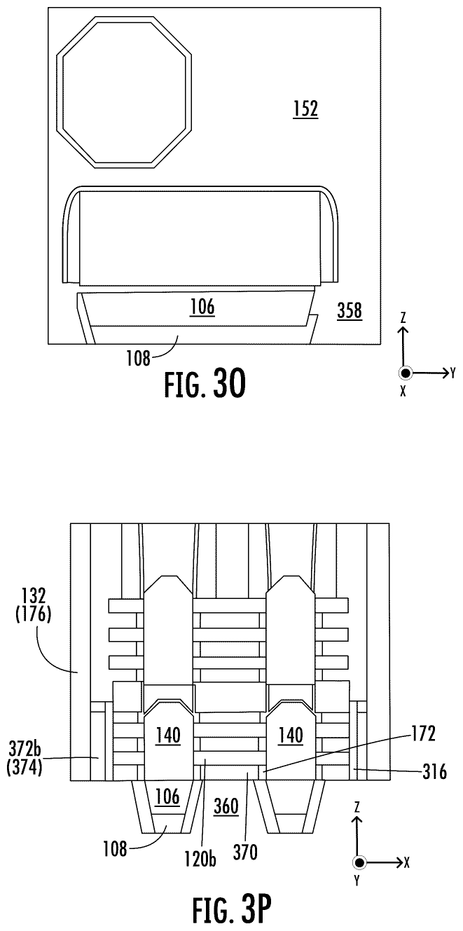

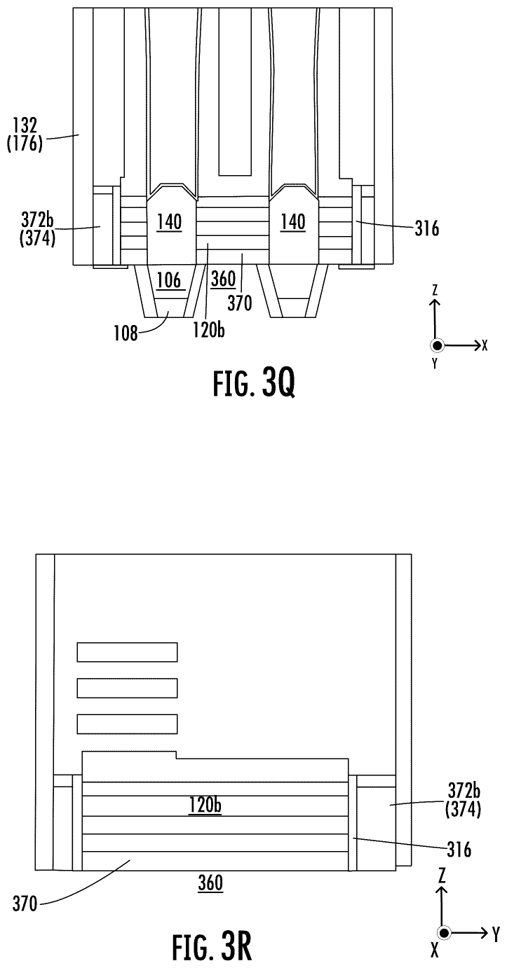

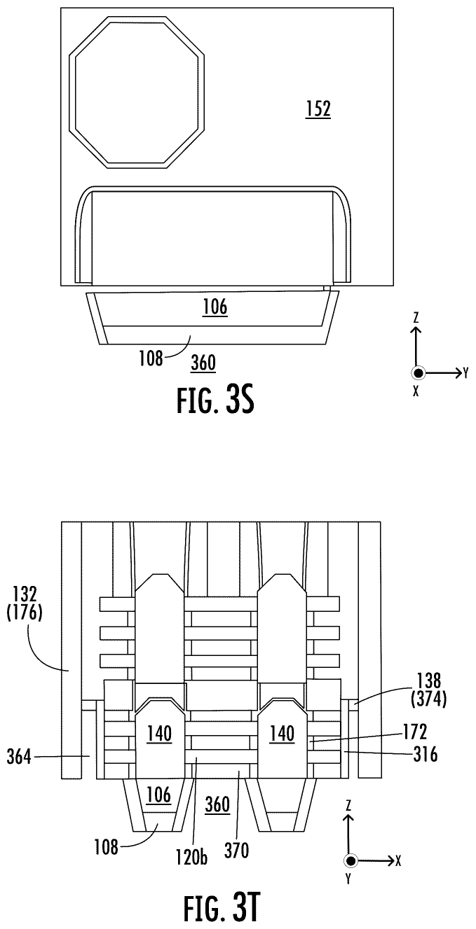

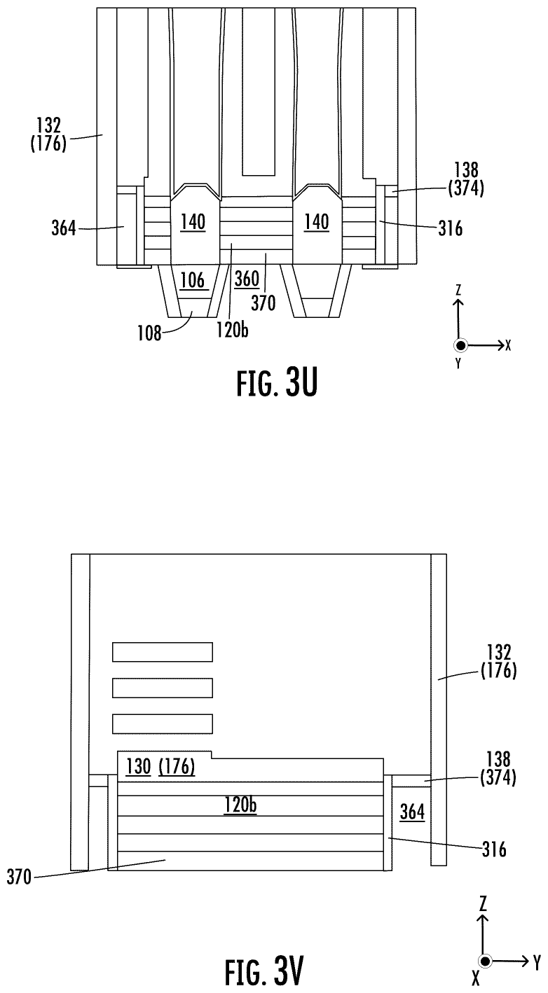

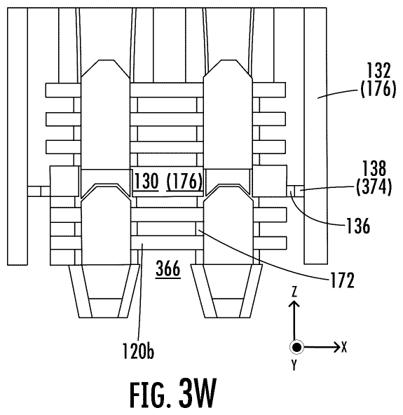

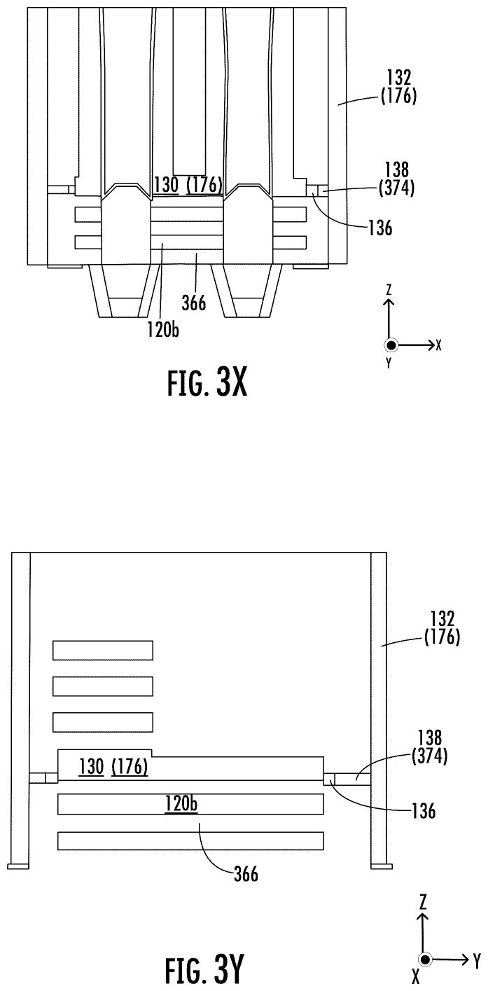

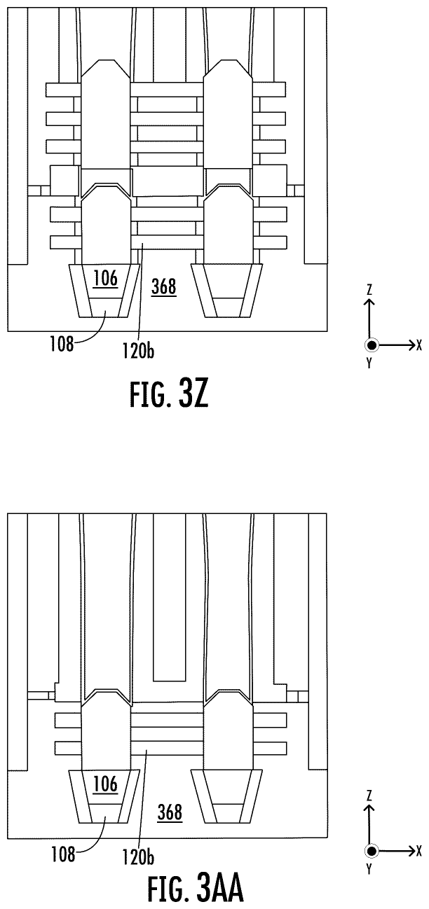

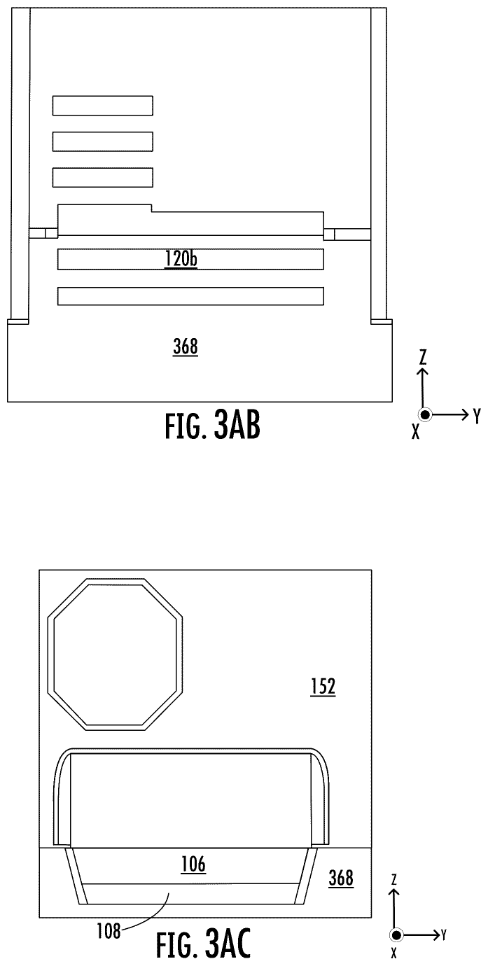

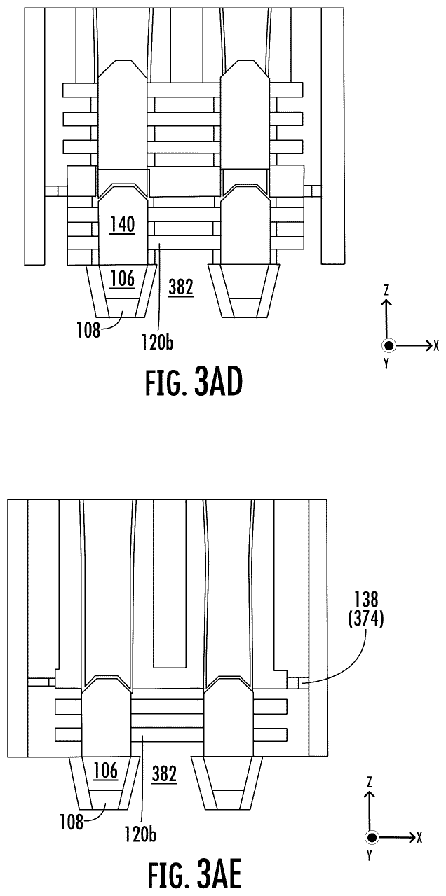

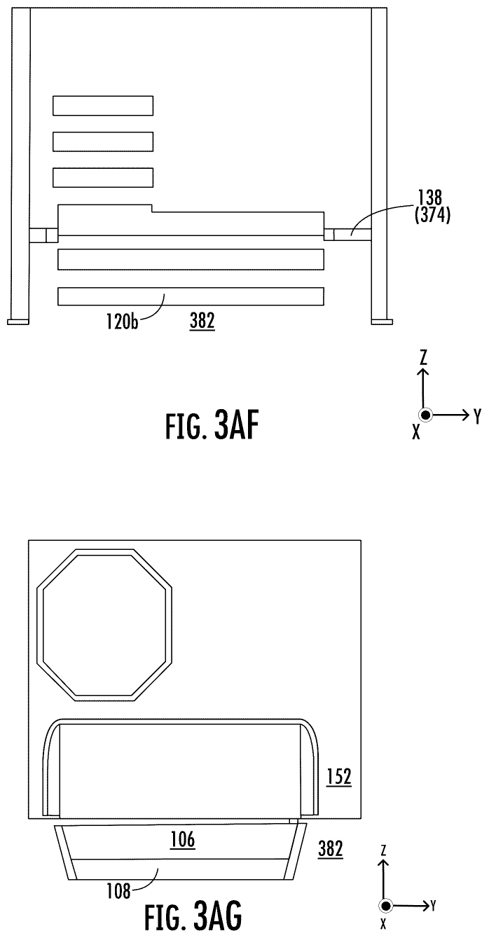

The insulating layer 138 may separate and electrically isolate the lower gate 170b (e.g., a lower gate material) from the upper gate 170a (e.g., an upper gate material). Unlike the spacer 130, however, the insulating layer 138 does not separate the lower channel layers 120b from the upper channel layers 120a. Accordingly, the insulating layer 138 may be between (in the vertical direction Z) the lower gate material and the upper gate material and not in a region in which the lower channel layers 120b are overlapped (in the vertical direction Z) by the upper channel layers 120a (e.g., not in a region that is between the lower channel layers 120b and the upper channel layers 120a). Moreover, the insulating layer 138 may serve as an etch-stop layer, which may be part of a multi-layer dummy gate structure 374 (FIG. 3A) that is used to form the transistor stack 101. The insulating layer 138 is not in the region in which the lower channel layers 120b are overlapped by the upper channel layers 120a because the insulating layer 138 is formed as the etch-stop layer in the multi-layer dummy gate structure 374 (where the etch-stop layer is formed outside of the stacks of lower channel layers 120b and upper channel layers 120a) and because a benefit of the insulating layer 138 is to separate the upper gate 170a from the lower gate 170b in regions where the spacer 130 does not already separate the lower channel layers 120b from the upper channel layers 120a.

The insulating layer 136 may be part of an insulating layer 316 (FIG. 3A) that is between the dummy gate structure 374 and the channel layers 120. According to some embodiments, the insulating layer 138 may include an insulating material that is different from that of the spacer 130 and different from that of the insulating layers 136, 152. For example, the insulating layer 138 may include nitrogen and may be free of boron, carbon, and oxygen. As an example, the insulating layer 138 may include silicon nitride (e.g., Si₃N₄).

In some embodiments, layers 106, 108 may be underneath the lower S/D regions 140. For example, the layers 106, 108 may be layers of multi-layer S/D contacts that are in contact with lower surfaces of the lower S/D regions 140. According to some embodiments, the layer 106 may comprise a different material from that of the layer 108. As an example, the layer 108 may be a spacer for the layer 106, and may include an insulating material such as silicon oxide and/or silicon nitride. Moreover, the layer 106 may be a placeholder (i.e., sacrificial) layer, such as silicon germanium, that may be replaced with another material (e.g., a metal or other conductive material).

FIG. 1D is an example cross-sectional view of the transistor device 100 along the line B-B′ of FIG. 1B. As shown in FIG. 1D, the insulating layer 138 separates the lower gate 170b and the upper gate 170a from each other, and does not overlap the lower channel layers 120b in the vertical direction Z.

For simplicity of illustration, insulating spacers 172 (FIG. 1C) are omitted from view in FIG. 1D. In some embodiments, however, the spacers 172 may be present between the lower S/D regions 140 and the lower gate 170b in the cross-section shown in FIG. 1D. Moreover, the insulating layer 138 may comprise the same insulating material (e.g., silicon nitride) as the spacers 172.

FIG. 1E is an example cross-sectional view of the transistor device 100 along the line C-C′ of FIG. 1B. As shown in FIG. 1E, the insulating layer 138 separates the lower gate 170b and the upper gate 170a from each other, and includes a sidewall that is on a sidewall of the spacer 130. In some embodiments, the insulating layer 136 may be between, in the lateral direction Y, the sidewall of the insulating layer 138 and the sidewall of the spacer 130. For example, a first sidewall of the insulating layer 136 may contact the sidewall of the spacer 130, and an opposite, second sidewall of the insulating layer 136 may contact the sidewall of the insulating layer 138. The lateral direction Y may be perpendicular to the sidewalls of the insulating layers 136, 138 and the spacer 130, and the vertical direction Z may be parallel to these sidewalls (and may be perpendicular to the upper surface of the lower gate 170b). As the spacer 130 comprises an insulating material that separates and electrically isolates the lower channel layers 120b from the upper channel layers 120a, the spacer 130 may also be referred to herein as an “isolation region.”

According to some embodiments, the insulating layer 138 may be wider, in the lateral direction Y, than the insulating layer 136. As a result, the insulating layer 138 may have a larger surface area (than the insulating layer 136) that is in contact with the lower surface of the upper gate 170a and a larger surface area (than the insulating layer 136) that is in contact with the upper surface of the lower gate 170b.

The insulating layer 138 (e.g., an inner sidewall thereof) may be adjacent, in the lateral direction Y, the sidewall of the spacer 130. As used herein with respect to the insulating layer 138 and the spacer 130, the term “adjacent” can mean that only the insulating layer 136 intervenes between the insulating layer 138 and the spacer 130 or that no layer intervenes between the insulating layer 138 and the spacer 130. Moreover, another (e.g., opposite, outer) sidewall of the insulating layer 138 may, in some embodiments, be collinear with a sidewall of the upper gate 170a, and/or collinear with a sidewall of the lower gate 170b, in the vertical direction Z.

FIG. 1E also shows that the spacer 130 may include an extension portion EP that vertically overlaps the lower channel layers 120b and is not vertically overlapped by the upper channel layers 120a. The upper gate 170a may vertically overlap the extension portion EP. In some embodiments, the lower channel layers 120b (e.g., lower nanosheets) may be wider, in the lateral direction Y, than the upper channel layers 120a (e.g., upper nanosheets). For example, the lower channel layers 120b may be more than twice as wide as the upper channel layers 120a. According to some embodiments, the spacer 130 may have the same width as the lower channel layers 120b. In contrast, the insulating layer 138 may be narrower, in the lateral direction Y, than the upper channel layers 120a (and thus also narrower than the lower channel layers 120b).

FIG. 1F is an example cross-sectional view of the transistor device 100 along the line D-D′ of FIG. 1B. As shown in FIG. 1F, the insulating layer 152 may provide a continuous perimeter around a cross-section of an upper S/D region 150. In some embodiments, an insulating layer 162 may be between the upper S/D region 150 and the insulating layer 152. Moreover, an insulating layer 164 may be between a lower S/D region 140 and the insulating layer 152, and an insulating layer 158 may be between the lower S/D region 140 and the insulating layer 164. According to some embodiments, the insulating layers 162, 164 may comprise the same insulating material (e.g., silicon nitride), which may be different from that of the insulating layer 152 (e.g., silicon oxide) and different from that of the insulating layer 158 (e.g., SiBCN). FIG. 1F also shows that the lower S/D region 140 may be wider, in the lateral direction Y, than the upper S/D region 150.

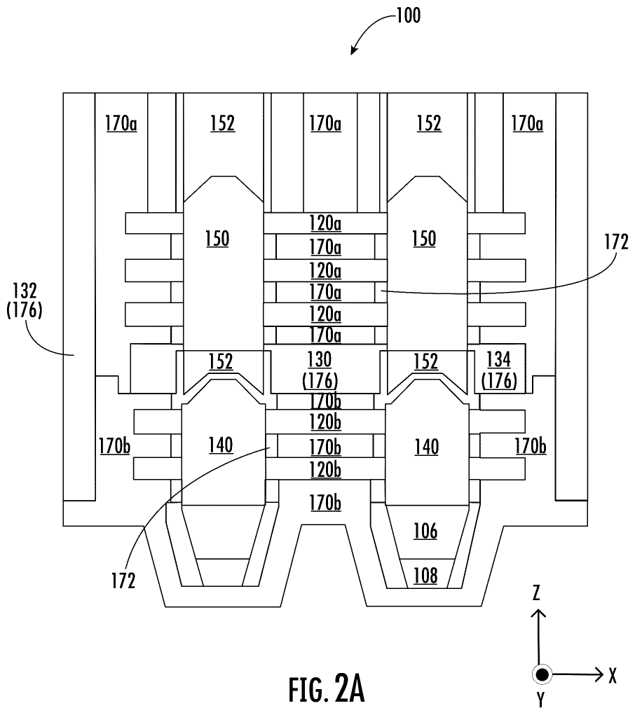

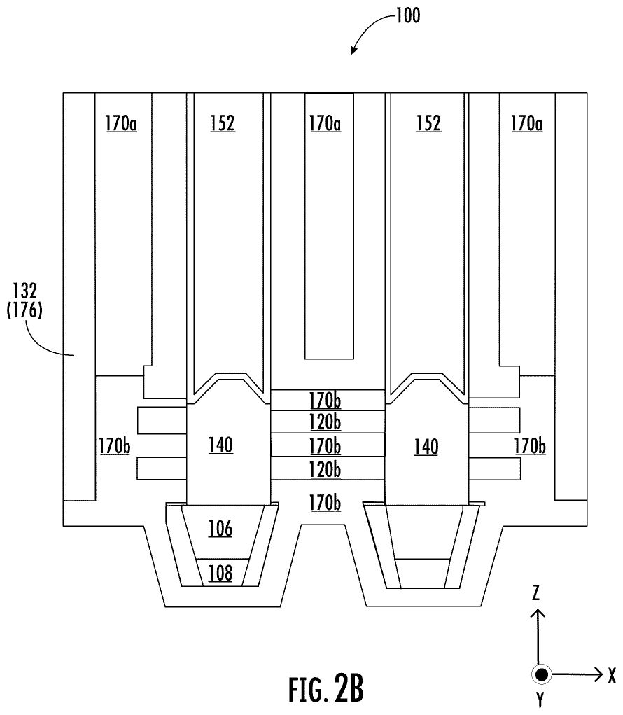

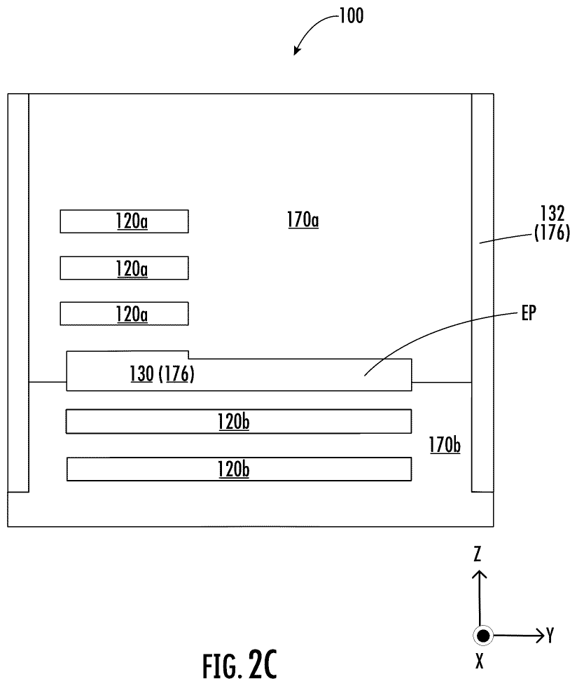

FIGS. 2A-2C show another example of the transistor device 100, where FIG. 2A is a cross-sectional view along the line A-A′ of FIG. 1B, FIG. 2B is a cross-sectional view along the line B-B′ of FIG. 1B, and FIG. 2C is a cross-sectional view along the line C-C′ of FIG. 1B. FIGS. 2A-2C differ from FIGS. 1C-1E, respectively, in that the insulating layer 138 (FIG. 1C) is omitted from the structure shown in the cross-sectional views of FIGS. 2A-2C. Accordingly, the upper gate 170a may contact the lower gate 170b, thereby providing a common gate structure, which is in contrast with the separated gate structure shown in FIGS. 1C-1E. In some embodiments, the insulating layer 136 (FIG. 1C) may also be omitted from the structure shown in FIGS. 2A-2C. Moreover, the transistor device 100 having the cross-sectional views shown in FIGS. 2A-2C may also have the cross-sectional view shown in FIG. 1F along the line D-D′ of FIG. 1B, as this cross-sectional view does not include the insulating layers 136, 138.

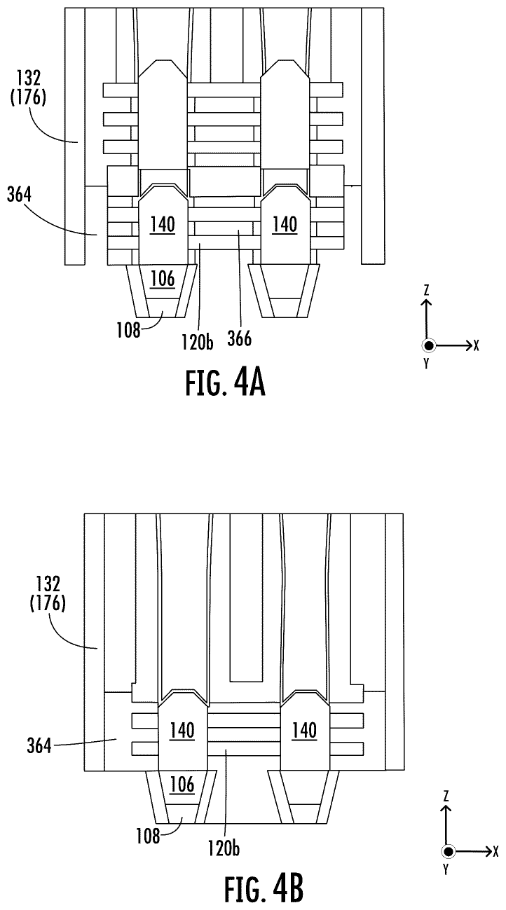

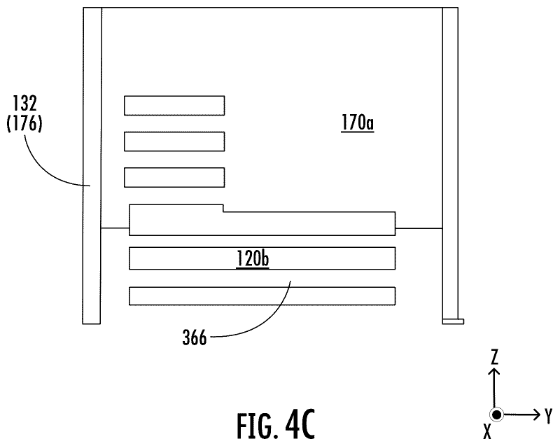

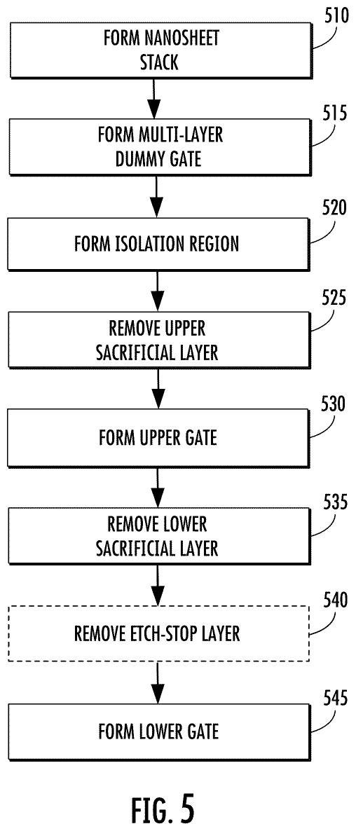

FIGS. 3A-3AG are cross-sectional views illustrating operations of forming the transistor device 100 of FIGS. 1C-IF. FIGS. 4A-4C are cross-sectional views illustrating an operation/process of forming the transistor device 100 of FIGS. 2A-2C. FIG. 5 is a flowchart corresponding to the operations shown in FIGS. 3A-3AG and 4A-4C.

FIGS. 3A, 3D, 3H, 3L, 3P, 3T, 3W, 3Z, and 3AD are cross-sectional views corresponding to the line A-A′ of FIG. 1B. FIGS. 3B, 3E, 3I, 3M, 3Q, 3U, 3X, 3AA, and 3AE are cross-sectional views corresponding to the line B-B′ of FIG. 1B. FIGS. 3C, 3F, 3J, 3N, 3R, 3V, 3Y, 3AB, and 3AF are cross-sectional views corresponding to the line C-C′ of FIG. 1B. FIGS. 3G, 3K, 30, 3S, 3AC, and 3AG are cross-sectional views corresponding to the line D-D′ of FIG. 1B. Moreover, FIGS. 4A, 4B, and 4C are cross-sectional views corresponding to the lines A-A′, B-B′, and C-C′, respectively, of FIG. 1B.

As shown in FIGS. 3A-3C and 5, the operations of forming the transistor device 100 may include forming (Block 510) stacks of semiconductor channel layers 120 on a substrate 310. In some embodiments, the channel layers 120 may be nanosheets, and the stacks may thus be nanosheet stacks. A lower stack comprises channel layers 120b, and an upper stack comprises channel layers 120a. The lower stack is separated from the upper stack by a sacrificial isolation layer 362. Moreover, sacrificial gate layers 370 may be alternately stacked on the substrate 310 with the channel layers 120. The sacrificial isolation layer 362 may be between upper ones of the sacrificial gate layers 370 and lower ones of the sacrificial gate layers 370.

The upper stack and the lower stack each form part of a transistor stack 101 (FIG. 1A). The lower channel layers 120b form part of a lower transistor Tb (FIG. 1A) of the transistor stack 101, and the upper channel layers 120a form part of an upper transistor Ta (FIG. 1A) of the transistor stack 101.

Though the plural term “stacks” is used in some examples herein for ease of differentiating between upper and lower ones of the channel layers 120, the singular term “stack” may also be used to describe the collective structure, as the upper channel layers 120a are stacked on top of the lower channel layers 120b. Accordingly, the term “nanosheet stack” may refer to either (i) a stack that includes both the upper channel layers 120a and the lower channel layers 120b, or (ii) a stack that includes one of only the upper channel layers 120a or only the lower channel layers 120b and is stacked with another stack that includes the other one of only the upper channel layers 120a or only the lower channel layers 120b.

The channel layers 120 are semiconductor layers that comprise, for example, silicon (e.g., polysilicon). In a subsequent operation/process, the sacrificial gate layers 370 may be replaced with an upper gate 170a and a lower gate 170b (FIG. 1C). Moreover, the sacrificial isolation layer 362 may be replaced with a spacer/MDI layer 130 (FIG. 1C) in a subsequent operation/process. The sacrificial gate layers 370 may comprise, for example, silicon germanium. Accordingly, the sacrificial gate layers 370 may have an etch selectivity relative to the channel layers 120. The sacrificial gate layers 370 may also have an etch selectivity relative to the sacrificial isolation layer 362. For example, the sacrificial isolation layer 362 and the sacrificial gate layers 370 may each comprise silicon germanium, but with different concentrations of germanium. As an example, the sacrificial isolation layer 362 may have a higher concentration of germanium (e.g., 55%) than the sacrificial gate layers 370 (e.g., 25%).

In some embodiments, an insulating layer 316 may be formed on sidewalls of the alternately-stacked channel layers 120 and sacrificial gate layers 370, and on an upper surface of an uppermost one of the upper channel layers 120a. Moreover, an insulating layer 312 may be formed in a recess of the substrate 310, and an insulating layer 314 may be formed in the recess on top of the insulating layer 312. The insulating layers 314, 316 may comprise the same insulating material (e.g., an oxide, such as silicon oxide), and may, in some embodiments, be a single, continuous layer having no visible/discernible interface or separation between the insulating layers 314, 316. The insulating material of the insulating layers 314, 316 may be different from that of the insulating layer 312, which may comprise, for example, a nitride (e.g., silicon nitride).

A multi-layer dummy gate structure 374 may be formed (Block 515) on the channel layers 120. The dummy gate structure 374 may include, for example, a lower sacrificial layer 372b, an upper sacrificial layer 372a, and an insulating layer 138 that is between, in the vertical direction Z, the sacrificial layers 372a, 372b. Accordingly, the dummy gate structure 374 may have three layers, and thus may be referred to herein as a “tri-layer” dummy gate structure in which the insulating layer 138 is the middle layer that separates the lower sacrificial layer 372b from the upper sacrificial layer 372a.

The upper sacrificial layer 372a may be on top of, and on sidewalls of, the upper channel layers 120a. The lower sacrificial layer 372b may be on sidewalls of the lower channel layers 120b. The insulating layer 138 may, in some embodiments, contact an upper surface of the lower sacrificial layer 372b, a lower surface of the upper sacrificial layer 372a, and a sidewall of the insulating layer 316. The sacrificial layers 372a, 372b may also contact the sidewall of the insulating layer 316. Accordingly, the insulating layer 316 may be between the dummy gate structure 374 and the channel layers 120.

The sacrificial layers 372a, 372b will be replaced with gates 170a, 170b (FIG. 1C) (e.g., WFM layers or other conductive gate materials) in a subsequent operation/process. The sacrificial layers 372a, 372b may each comprise a semiconductor material, and thus may each be referred to herein as a “semiconductor sacrificial layer.” The semiconductor material may comprise, for example, polysilicon, and may have an etch selectivity with respect to the channel layers 120, the sacrificial gate layers 370, and/or the sacrificial isolation layer 362.

As shown in FIGS. 3D-3G, the dummy gate structure 374 may be etched to form openings therein. For example, the upper sacrificial layer 372a may be etched to expose sidewalls of the upper sacrificial layer 372a and an upper surface of an uppermost one of the upper channel layers 120a. In some embodiments, the etching may be reactive-ion etching (RIE). As an example, an etch mask (e.g., a hard mask) may be formed and patterned on an upper surface of the upper sacrificial layer 372a, and then the RIE may be performed while the etch mask is in place. Moreover, the insulating layer 138 and the lower sacrificial layer 372b may be etched by the RIE to expose portions of an upper surface of the insulating layer 314.

Referring to FIGS. 3D-3G together with FIG. 5, an insulating layer/material 176 that includes an MDI spacer 130 and vertical portions 132 may be formed (Block 520) after etching the dummy gate structure 374 and the sacrificial isolation layer 362. For example, the vertical portions 132 may be conformally formed on the dummy gate structure 374 after the RIE, and may thereby provide gate spacers on sidewalls of the dummy gate structure 374. Moreover, the sacrificial isolation layer 362 (FIGS. 3A-3C) may be removed by performing a selective etch that leaves the sacrificial gate layers 370 between the channel layers 120. The spacer 130, which may also be referred to herein as an “isolation region,” may be formed in an opening that is formed by removing the sacrificial isolation layer 362.

FIGS. 3D-3F also show that insulating layers 352, 354 may be formed on an upper surface of the upper sacrificial layer 372a, between opposite sidewalls of the vertical portions 132. The insulating layers 352, 354 may comprise different insulating materials from each other and from the vertical portions 132. As an example, the insulating layer 352 may comprise silicon nitride, and the insulating layer 354 may comprise silicon oxide.

Referring to FIG. 3G, an insulating layer 356 may be formed on the insulating layer/material 176 and on the channel layers 120. For example, the insulating layer 356 may contact sidewalls of the upper channel layers 120a. Moreover, an insulating layer 158 (e.g., SiBCN) may be formed on sidewalls of the lower channel layers 120b, and the insulating layer 356 may be formed on the insulating layer 158. In some embodiments, the insulating layer 356 may comprise a different insulating material from that of the insulating layer 158. The insulating layer 356 may thus subsequently be removed without removing the insulating layer 158.

As shown in FIGS. 3H-3K, lower S/D regions 140 and upper S/D regions 150 may be formed in openings that are etched in the dummy gate structure 374. In some embodiments, the S/D regions 140, 150 may be formed by epitaxial growth. For example, the lower S/D regions 140 may be epitaxially grown from the lower channel layers 120b, and the upper S/D regions 150 may be epitaxially grown from the upper channel layers 120a. According to some embodiments, the channel layers 120 may comprise silicon, and the lower S/D regions 140 and/or the upper S/D regions 150 may comprise silicon, silicon carbide, or silicon germanium. Insulating layers 152, 178 may also be formed in the openings, and insulating spacers 172 may be formed on sidewalls of the sacrificial gate layers 370 through the openings.

The insulating layer 152 may, in some embodiments, be formed between, in the vertical direction Z, the lower and upper S/D regions 140, 150, and on an upper surface of each of the upper S/D regions 150. According to some embodiments, a planarization operation/process (e.g., chemical-mechanical planarization (CMP)) may be performed after forming the insulating layers 132, 152. Moreover, the insulating layers 132, 134 may comprise the same insulating material (e.g., SiBCN) as the spacer 130, and this insulating material may be different from that of the insulating layers 152, 314, 316 (e.g., an oxide).

In some embodiments, the insulating spacers 172 may be formed on sidewalls of the sacrificial gate layers 370 and between, in the vertical direction Z, the channel layers 120. For example, the sacrificial gate layers 370 may be etched to form openings in the sacrificial gate layers 370 between the channel layers 120. Sidewalls of the sacrificial gate layers 370 may be exposed through the openings, and the spacers 172 may be formed in the openings. The spacers 172 may comprise the same insulating material (e.g., silicon nitride) as the insulating layers 312, 138, 178, which may be different from the insulating material of the insulating layer 152 and different from the insulating material of the insulating layers 132, 134.

FIGS. 3H and 3I show that a layer 106 may be formed on lower surfaces of the lower S/D regions 140. In some embodiments, the layer 106 may comprise a conductive material that is part of an S/D contact. In other embodiments, the layer 106 may be a sacrificial (e.g., silicon germanium) layer that will be replaced with a conductive (e.g., metal) material.

FIG. 3K shows that the upper stack in FIG. 3G may be replaced with an upper S/D region 150, and the lower stack in FIG. 3G may be replaced with a lower S/D region 140. Moreover, the insulating layer 356 may be replaced with the insulating layer 152.

Referring to FIGS. 3H-3K together with FIG. 5, the upper sacrificial layer 372a (FIG. 3D) and upper ones of the sacrificial gate layers 370 may be removed (Block 525) and an upper gate 170a may be formed (Block 530) in the place of the upper sacrificial layer 372a and the upper ones of the sacrificial gate layers 370. For example, a replacement polysilicon gate (RPG), or replacement metal gate (RMG), operation/process may be performed with respect to the upper sacrificial layer 372a and the upper ones of the sacrificial gate layers 370. The RPG (or RMG) operation/process may include removing polysilicon and replacing it with a non-polysilicon conductive gate material. The upper gate 170a may thus comprise a metal, or other non-polysilicon conductive, gate.

In some embodiments, removal of the upper sacrificial layer 372a may include etching (e.g., patterning/recessing) the upper sacrificial layer 372a to form openings therein. The openings may remove the upper sacrificial layer 372a from between sidewalls of the vertical portions 132, and may thereby expose the sidewalls of the vertical portions 132. Moreover, an upper surface of an extension portion EP of the spacer 130 may be exposed, sidewalls of the upper channel layers 120a may be exposed, and an upper surface of the insulating layer 138 may be exposed. As an example, the insulating layer 138 may serve as an etch-stop layer when removing the upper sacrificial layer 372a. The upper gate 170a (i.e., an upper gate material) may then be formed in the openings and in the place of the upper ones of the sacrificial gate layers 370.

According to some embodiments, the upper gate 170a may comprise an upper WFM layer, which may be between the upper channel layers 120a, on the exposed sidewalls of the upper channel layers 120a, on the extension portion EP of the spacer 130, and on the upper surface of the insulating layer 138, as shown in FIG. 3J. The upper WFM layer may be formed by, for example, metal deposition in the openings, followed by a metal CMP operation/process.

As shown in FIGS. 3L-30, a back-end-of-line (BEOL) operation/process may be performed and a self-aligned contact (SAC) operation/process may be performed. As a result, the substrate 310 may be replaced with a placeholder (i.e., sacrificial) material 358 for a lower gate 170b (FIG. 1E) that will subsequently be formed, and a layer 108 may be formed on sidewalls and a lower surface of the layer 106. In some embodiments, the placeholder material 358 may comprise an insulating layer, such as an oxide layer.

As shown in FIGS. 3P-3S, the placeholder material 358 (FIG. 30) may be removed, thereby forming an opening 360 that may expose sidewalls of the layer 108. For example, the placeholder material 358 may be an oxide (or other dielectric) layer that is removed by an oxide (or other dielectric) removal operation/process. In some embodiments, the opening 360 may also expose a lower surface of a lowermost one of the sacrificial gate layers 370 and a lower surface of the lower sacrificial layer 372b.

As shown in FIGS. 3T-3V and 5, the lower sacrificial layer 372b may be removed (Block 535), thereby forming an opening 364 that exposes a lower surface of the insulating layer 138. For example, the lower sacrificial layer 372b may be removed by a polysilicon removal operation/process that is performed on the back side of the structure shown in FIGS. 3P-3R while the insulating layer 138 serves as an etch-stop layer.

As shown in FIGS. 3W-3Y, openings 366 may be formed by removing a lower portion of the insulating layer 316 (FIG. 3V) and removing lower ones of the sacrificial gate layers 370 (FIG. 3V). As an example, the insulating layer 316 may be recessed by an oxide removal operation/process, which may stop at the insulating layer 138 (which serves as an etch-stop layer). A remaining (e.g., upper) portion of the insulating layer 316 may provide the insulating layer 136 that is laterally adjacent (e.g., in contact with a sidewall of) the insulating layer 138. In some embodiments, the insulating layer 316 may be recessed by an extra gate (EG) oxide removal operation/process. Moreover, the sacrificial gate layers 370 may be removed from between the lower channel layers 120b, as the sacrificial gate layers 370 may have an etch selectivity relative to the lower channel layers 120b. As a result of removing/recessing the lower sacrificial layer 372b, the sacrificial gate layers 370, and the insulating layer 316, upper and lower surfaces of the lower channel layers 120b may be exposed, as may lower sidewalls of the vertical portions 132 and a lower surface of the spacer 130.

As shown in FIGS. 3Z-3AC, a mask 368 may, in some embodiments, be formed in the openings 366 (FIG. 3Y) and on the layers 106, 108. For example, the mask 368 may selectively be formed in/on (e.g., on a back side of) one or more transistor stacks 101 (FIG. 1A) and not in/on other transistor stacks 101. The mask 368 may be used to protect the insulating layer 138 from removal in the one or more transistor stacks 101 while the insulating layer 138 is being removed from the other transistor stacks 101. A separated gate structure may be facilitated by maintaining the insulating layer 138 in the one or more transistor stacks 101, and a common gate structure may be facilitated by removing the insulating layer 138 from the other transistor stacks 101. Accordingly, forming the mask 368 in selective regions (e.g., selective ones of the transistor stacks 101) can facilitate selectively forming separated gate structures, which may share a transistor device 100 (FIG. 1A) with common gate structures.

As shown in FIGS. 3AD-3AG, the mask 368 (FIG. 3AC) may be removed, thereby forming openings 382. According to some embodiments, the openings 382 may be the same (e.g., may expose the same layers) as the openings 366 (FIG. 3Y).

As shown in FIGS. 1C-IF and 5, a lower gate 170b (i.e., a lower gate material) may be formed (Block 545) in the openings 382 (FIG. 3AF). In some embodiments, the lower gate 170b may comprise a lower WFM layer, which may be between the lower channel layers 120b. The lower WFM layer may be formed by, for example, metal deposition in the openings 382, followed by a metal CMP operation/process. Moreover, the lower gate 170b may be formed on a lower surface of the insulating layer 138, thereby providing a separated gate structure in which the insulating layer 138 separates the upper gate 170a from the lower gate 170b. The upper gate 170a and the lower gate 170b in the separated gate structure are thus not in contact with each other.

According to some embodiments, the lower WFM layer of the lower gate 170b may comprise a first metal (e.g., aluminum), and the upper WFM layer of the upper gate 170a may comprise a second metal (e.g., titanium nitride) that is different from the first metal. Moreover, the lower gate 170b may include a high-k material (e.g., together with metal) in some embodiments, where the term “high-k” refers to a higher dielectric constant than silicon dioxide. In other embodiments, the lower gate 170b may include doped polysilicon. Though omitted from view in FIGS. 1C-IF and 5 for simplicity of illustration, gate insulation layers may, according to some embodiments, be formed between each metal layer and the channel layers 120.

FIGS. 4A-4C are cross-sectional views illustrating an operation/process that can be performed to form transistor stacks 101 (FIG. 1A) having common gate structures, such as the common gate structure that is shown in FIGS. 2A-2C. These structures may be referred to herein as “common gate” (rather than separated gate) structures, as a transistor stack 101 may have an upper gate 170a that is in contact with a lower gate 170b instead of being separated from each other by an insulating layer 138 (FIG. 1E). In some embodiments, the operation/process shown in FIGS. 4A-4C may be performed after performing the operations shown in FIGS. 3A-3Y.

As shown in FIGS. 4A-4C together with FIG. 5, the operation/process may include removing (Block 540) the insulating layer 138 (FIG. 3Y) after removing the lower sacrificial layer 372b (FIG. 3R) while using the insulating layer 138 as an etch-stop layer. As a result, a lower surface of the upper gate 170a may be exposed. Removal of the insulating layer 138 may be performed by, for example, selectively etching the insulating layer 138 relative to the vertical portions 132. A lower gate 170b (FIG. 2C) may be formed in the openings 366 after removing the insulating layer 138, thereby providing a transistor stack 101 having the structure shown in FIGS. 2A-2C. This structure may differ from the structure shown in FIGS. 1C-1E, in that the insulating layer 138 is omitted and an upper surface of the lower gate 170b is in contact with the lower surface of the upper gate 170a.

In some embodiments, the operations of FIGS. 3A-3AG, 4A-4C, and 5 may form multiple transistor stacks 101 in a transistor device 100 (FIG. 1A). For example, the operation/process shown in FIGS. 4A-4C may be performed on transistor stacks 101 in one region while the mask 368 (FIG. 3Z) protects the insulating layer 138 from removal from transistor stacks 101 in other regions. Accordingly, transistor stacks 101 having a common gate structure may be formed concurrently with transistor stacks 101 having a separated gate structure.

Transistor devices 100 (FIG. 1A) according to embodiments herein may provide various advantages. These advantages include improved control of a process variation for forming an upper gate material and a lower gate material (e.g., different WFMs) for an upper transistor Ta (FIG. 1A) and a lower transistor Tb (FIG. 1A) of a transistor stack 101 (FIG. 1A). In some embodiments, the upper gate material and the lower gate material may be electrically isolated from each other in a separated gate structure, which can help to reduce an area of a transistor device 100. Moreover, the same manufacturing process (e.g., the same integration flow) may be used to concurrently form (i) at least one transistor stack 101 having a common gate structure and (ii) at least one transistor stack 101 having the separated gate structure in selective regions, respectively. For example, one area of a transistor device 100 may have a transistor stack 101 having the common gate structure and another area of the transistor device 100 may have a transistor stack 101 having the separated gate structure. The separated gate structure may be provided by forming an upper gate 170a (FIG. 1E) (e.g., an upper gate material) and a lower gate 170b (FIG. 1E) (e.g., a lower gate material) that are separated from each other by an insulating layer 138 (FIG. 1E) that is part of a multi-layer dummy gate structure 374 (FIG. 3C).

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

It should also be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present invention.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A stacked field-effect transistor (FET) device comprising:
a lower FET comprising lower channel layers and a lower gate material that is between the lower channel layers;
an upper FET that is on the lower FET, the upper FET comprising upper channel layers and an upper gate material that is between the upper channel layers; and
an insulating layer that is between the lower gate material and the upper gate material and not in a region in which the lower channel layers are overlapped by the upper channel layers.

2. The stacked FET device of claim 1, wherein the insulating layer is in contact with a lower surface of the upper gate material and an upper surface of the lower gate material.

3. The stacked FET device of claim 2, wherein the insulating layer does not overlap the lower channel layers in a vertical direction that is perpendicular to the upper surface of the lower gate material.

4. The stacked FET device of claim 1, further comprising an isolation region that separates the lower channel layers from the upper channel layers,
wherein a sidewall of the insulating layer is on a sidewall of the isolation region.

5. The stacked FET device of claim 4, wherein the insulating layer comprises an etch-stop layer that is thinner than the isolation region in a vertical direction that is parallel to the sidewall of the isolation region.

6. The stacked FET device of claim 4, wherein the insulating layer and the isolation region comprise different insulating materials from each other.

7. The stacked FET device of claim 6, wherein the insulating layer comprises silicon nitride.

8. The stacked FET device of claim 4,
wherein the insulating layer is a first insulating layer, and
wherein the stacked FET device further comprises a second insulating layer that is between the first insulating layer and the isolation region.

9. The stacked FET device of claim 8, wherein the second insulating layer comprises:
a first sidewall that is in contact with the sidewall of the isolation region; and
a second sidewall that is in contact with the sidewall of the first insulating layer.

10. The stacked FET device of claim 8, wherein the second insulating layer comprises an insulating material different from that of the first insulating layer and different from that of the isolation region.

11. The stacked FET device of claim 10,
wherein the insulating material of the second insulating layer comprises an oxide and is free of carbon and boron, and
wherein the first insulating layer comprises nitrogen and is free of carbon, boron, and oxygen.

12. The stacked FET device of claim 10, wherein the isolation region comprises silicon boron carbonitride.

13. The stacked FET device of claim 8, wherein the second insulating layer is thinner than the isolation region in a vertical direction that is parallel to the sidewall of the isolation region.

14. The stacked FET device of claim 8, wherein the first insulating layer is wider, in a lateral direction that is perpendicular to the sidewall of the isolation region, than the second insulating layer.

15. A stacked field-effect transistor (FET) device comprising:
a lower FET comprising lower channel layers and a lower gate material that is between the lower channel layers;
an upper FET that is on the lower FET, the upper FET comprising upper channel layers and an upper gate material that is between the upper channel layers;
an isolation region that separates the lower channel layers from the upper channel layers; and
an insulating layer that separates the lower gate material from the upper gate material and is adjacent a sidewall of the isolation region.

16. The FET device of claim 15, wherein the insulating layer comprises silicon nitride and is thinner than the isolation region in a vertical direction that is parallel to the sidewall of the isolation region.

17. A method of forming a stacked field-effect transistor (FET) device, the method comprising:
forming a nanosheet stack and a multi-layer dummy gate structure on the nanosheet stack, wherein the nanosheet stack comprises lower channel layers and upper channel layers that are on the lower channel layers, and wherein the multi-layer dummy gate structure comprises an upper semiconductor sacrificial layer, a lower semiconductor sacrificial layer, and an etch-stop layer that is between the lower semiconductor sacrificial layer and the upper semiconductor sacrificial layer;
removing the upper semiconductor sacrificial layer to expose an upper surface of the etch-stop layer;
forming an upper gate material between the upper channel layers and on the upper surface of the etch-stop layer;
removing the lower semiconductor sacrificial layer to expose a lower surface of the etch-stop layer, after forming the upper gate material; and
forming a lower gate material between the lower channel layers, after removing the lower semiconductor sacrificial layer.

18. The method of claim 17, wherein forming the lower gate material comprises forming the lower gate material on the lower surface of the etch-stop layer.

19. The method of claim 17, further comprising:
forming a mask on a back side of another nanosheet stack; and
removing the etch-stop layer before forming the lower gate material, while the mask is on the back side of the other nanosheet stack,
wherein forming the lower gate material comprises forming the lower gate material in contact with a lower surface of the upper gate material.

20. The method of claim 17, further comprising forming an isolation region that separates the lower channel layers from the upper channel layers, after forming the multi-layer dummy gate structure,
wherein forming the upper gate material comprises forming the upper gate material on the isolation region,
wherein the etch-stop layer is adjacent a sidewall of the isolation region, and
wherein the etch-stop layer is thinner than the isolation region in a vertical direction that is parallel to the sidewall of the isolation region.
